(19) United States
(12) Patent Application Publication
(10) Pub. No.: US 2024/0134406 A1
(43) Pub. Date: Apr. 25, 2024

(54) ELECTRONIC CIRCUIT COMPRISING A REFERENCE VOLTAGE CIRCUIT AND A START CHECK CIRCUIT

(71) Applicants: STMicroelectronics (Grenoble 2) SAS, Grenoble (FR); STMicroelectronics (Alps) SAS, Grenoble (FR)

(72) Inventors: Julien GOULIER, Grenoble (FR); Nicolas GOUX, Saint-Martin-d'Heres (FR); Marc JOISSON, Brie et Angonnes (FR)

(73) Assignees: STMicroelectronics (Grenoble 2) SAS, Grenoble (FR); STMicroelectronics (Alps) SAS, Grenoble (FR)

(21) Appl. No.: 18/379,262

(22) Filed: Oct. 11, 2023

(30) Foreign Application Priority Data
Oct. 23, 2022 (FR) 2211019

(51) Int. Cl. G05F 3/26; G05F 1/46; H03K 17/18; H03K 17/22

(52) U.S. Cl. CPC G05F 3/262; G05F 1/468; H03K 17/18; H03K 17/22; H03F 3/45179

(57) ABSTRACT

An electronic circuit includes a reference voltage circuit and a circuit for checking the starting operation of the reference voltage circuit. The reference voltage circuit includes a first stack of a first transistor and second transistor receiving first and second control signals, respectively. The start check circuit includes a first elementary test circuit including a second stack of a third transistor and fourth transistor receiving the first and second control signals, respectively. An output of the first elementary test circuit delivers a first binary signal indicative of proper starting operation of the reference voltage circuit.

### PRIORITY CLAIM

This application claims the priority benefit of French Application for Patent No. 2211019, filed on Oct. 24, 2022, the content of which is hereby incorporated by reference in its entirety to the maximum extent allowable by law.

### TECHNICAL FIELD

The present disclosure generally concerns reference voltage circuits and, in particular, an electronic circuit comprising a reference voltage circuit and a circuit for checking the starting operation (i.e., start-up) of the reference voltage circuit.

### BACKGROUND

A reference voltage circuit is an electronic circuit delivering a reference voltage, that is, a constant voltage which is substantially independent from temperature and from the power supply voltage. This reference voltage is used by other elements of the electronic circuit. The reference voltage circuit is powered by a source of a power supply voltage external to the electronic circuit.

For certain applications, for example, for banking applications, it is necessary to verify that the reference voltage circuit has correctly started when the power supply voltage increases from zero volts to a nominal value. For this purpose, the electronic circuit comprises a start check circuit that can copy the general structure of the reference voltage circuit. The reference voltage circuit delivers test signals representative of the state of the inner nodes which are compared with the same signals delivered by the start check circuit. If the starting operation of the reference voltage circuit occurs normally, it is assumed that the test signals delivered by the reference voltage circuit and the start check circuit have to be identical. When the test signals delivered by the reference circuit and the start check circuit are different, this means that the starting operation of the reference voltage circuit has not occurred correctly.

A disadvantage of such a start check circuit is that it has a complex structure since it generally copies the structure of the reference voltage circuit, and it occupies a significant surface area of the total surface area of the electronic circuit, particularly when this circuit is formed in integrated fashion.

There is a need in the art to overcomes all or part of the disadvantages of known electronic circuits comprising a reference voltage circuit and a circuit for checking the starting operation of the reference voltage circuit.

### SUMMARY

In an embodiment, the surface area occupied by the start check circuit is decreased with respect to the surface area occupied by the reference voltage circuit when these circuits are formed in integrated fashion.

In an embodiment, the structure of the start check circuit is simple.

An electronic circuit comprises: a reference voltage circuit and a circuit for checking the starting operation of the reference voltage circuit. The reference voltage circuit comprises at least one first stack of a first transistor, comprising a first control terminal receiving a first control signal, and of a second transistor, comprising a second control terminal receiving a second control signal. The start check circuit comprises at least one first elementary test circuit comprising a second stack of a third transistor and of a fourth transistor, the third transistor being of the same type as the first transistor and comprising a third control terminal receiving the first control signal, the fourth transistor being of the same type as the second transistor and comprising a fourth control terminal receiving the second control signal, the first elementary test circuit being configured to deliver a first binary signal.

According to an embodiment, the reference voltage circuit is intended to be connected to a source of a power supply voltage and to a source of a reference potential. The first transistor and the second transistor are series-coupled between the source of the power supply voltage and the source of the reference potential, and the third transistor and the second transistor are series-coupled between the source of the power supply voltage and the source of the reference potential.

According to an embodiment, the first, second, third, and fourth transistors are MOS transistors.

According to an embodiment, the first transistor and the second transistor are of the same type, and the first elementary test circuit further comprises a fifth transistor in series with a sixth transistor, the fifth transistor comprises a fifth control terminal receiving the first control signal and the sixth transistor comprising a sixth control terminal receiving a signal at an intermediate node of the second stack, the first binary signal corresponding to the voltage at the junction node between the fifth transistor and the sixth transistor.

According to an embodiment, the reference voltage circuit comprises at least one third stack of a seventh transistor, comprising a seventh control terminal receiving a third control signal, and of an eighth transistor, comprising an eighth control terminal receiving a fourth control signal, and the start check circuit comprises at least one second elementary test circuit comprising a fourth stack of a ninth transistor and of a tenth transistor, the ninth transistor being of the same type as the seventh transistor and comprising a ninth control terminal receiving the third control signal, the tenth transistor being of the same type as the eighth transistor and comprising a tenth control terminal receiving the fourth control signal, the second elementary test circuit being configured to deliver a second binary signal.

According to an embodiment, the third control signal is identical to the first control signal.

According to an embodiment, the seventh transistor and the eighth transistor are series-coupled between the source of the power supply voltage and the source of the reference potential, and the ninth transistor and the tenth transistor are series-coupled between the source of the power supply voltage and the source of the reference potential.

According to an embodiment, the seventh transistor and the eighth transistor are of different types, and the second binary signal corresponds to the voltage at the junction node between the ninth transistor and the tenth transistor.

According to an embodiment, the seventh, eighth, ninth, and tenth transistors are MOS transistors.

According to an embodiment, the electronic circuit comprises a proportional to absolute temperature (PTAT) circuit, a first amplification stage, and a second amplification stage, the first amplification stage comprising an eleventh transistor and a twelfth transistor, the second control signal being the voltage at a power terminal of the eleventh transistor, and the fourth control signal being the voltage at a power terminal of the twelfth transistor.

An embodiment also provides a method of designing an electronic circuit comprising a reference voltage circuit and a circuit for checking the starting operation of the reference voltage circuit, the method comprising the following steps: determining, in the reference voltage circuit, at least one first stack of a first transistor, comprising a first control terminal receiving a first control signal, and of a second transistor, comprising a second control terminal receiving a second control signal; and adding in the start check circuit at least one first elementary test circuit comprising a second stack of a third transistor and of a fourth transistor, the third transistor being of the same type as the first transistor and comprising a third control terminal receiving the first control signal, the fourth transistor being of the same type as the second transistor and comprising a fourth control terminal receiving the second control signal, the first elementary test circuit being configured to deliver a first binary signal.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an electric diagram of a reference voltage circuit and of a start check circuit;

FIG. 2 shows an embodiment of a reference voltage circuit;

FIG. 3 is a block diagram of an embodiment of a circuit for checking the starting operation of a reference voltage circuit;

FIG. 4 shows a circuit comprising the reference voltage circuit of FIG. 2 and an embodiment of a start check circuit;

FIG. 5 shows an embodiment of an elementary test circuit of the start check circuit of FIG. 4;

FIG. 6 shows an embodiment of another elementary test circuit of the start check circuit of FIG. 4;

FIG. 7 shows timing diagrams of voltages of the circuit of FIG. 2; and

FIG. 8 shows another embodiment of a reference voltage circuit.

### DETAILED DESCRIPTION

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless specified otherwise, the expressions “around”, “approximately”, “substantially” and “in the order of” signify within 10%, and preferably within 5%.

Further, a “binary signal” is a signal which alternates between a first constant state, for example, a low state, noted “0”, and a second constant state, for example, a high state, noted “1”. The high and low states of different binary signals of a same electronic circuit may be different. In practice, the binary signals may correspond to voltages or to currents which may not be perfectly constant in the high or low state. In the following description, the source and the drain of a MOS transistor are referred to as “power terminals” of the MOS transistor and the collector and the emitter of a bipolar transistor are referred to as “power terminals” of the bipolar transistor. Further, the gate of the MOS transistor is referred to as the “control terminal” of the MOS transistor and the base of the bipolar transistor is referred to as the “control terminal” of the bipolar transistor. Further, unless indicated otherwise, when it is spoken of a voltage at a node, there is considered the difference between the potential at said node and a reference potential, for example, the ground, taken as equal to 0 V.

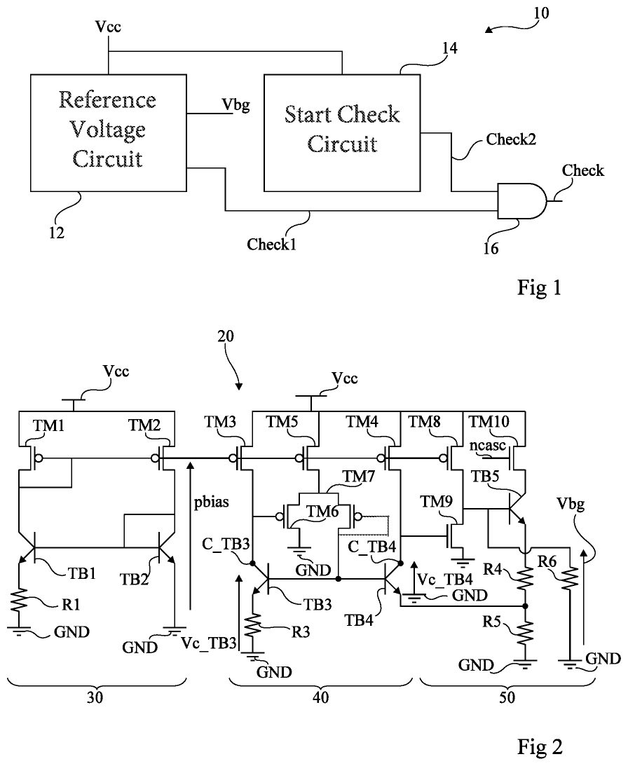

FIG. 1 partially and schematically shows an electronic circuit 10 comprising a reference voltage circuit 12 powered with a power supply voltage Vcc and delivering a reference voltage Vbg, that is, a voltage which is substantially constant and independent from temperature and from the power supply voltage.

For certain applications, for example, for banking applications, it is necessary to check that reference voltage circuit 12 has correctly started when power supply voltage Vcc increases from 0 V to a nominal value. For this purpose, electronic circuit 10 comprises a start check circuit 14. According to an example, the start check circuit 14 may partly or totally copy the structure of reference voltage circuit 12 (in other words, use replica circuits). Reference voltage circuit 12 delivers binary signals Check1, representative of the state of inner nodes of reference voltage circuit 12, and start check circuit 14 delivers the same binary signals Check2. A logic circuit 16, for example, an AND-type logic gate, receives as inputs binary signals Check1 and Check2 and delivers a binary signal Check. If the starting operation of reference voltage circuit 12 occurs normally, it is assumed that binary signals Check1 and binary signals Check2 have to be identical. Binary signal Check is, for example, at logic state “1”. When binary signal Check is at logic state “0”, this means that the starting operation of reference voltage circuit 12 has not occurred correctly.

A disadvantage of check circuit 14 is that it has a complex structure since it at least partially copies the structure of reference voltage circuit 12, and that it occupies a significant surface area of the total surface area of circuit 10 when circuit 10 is formed in integrated fashion.

FIG. 2 is an electric diagram of an embodiment of a reference voltage circuit 20.

Reference voltage circuit 20 comprises a proportional to absolute temperature (PTAT) circuit 30 for delivering a bias voltage pbias, a first amplification stage 40, and a second amplification stage 50.

The PTAT circuit 30 comprises: a bipolar transistor TB1, for example, of NPN type, having its emitter coupled, preferably connected, to a terminal of a resistor R1, the other terminal of resistor R1 being coupled, preferably connected, to a source of a low reference potential GND, for example, the ground; a bipolar transistor TB2, for example, of NPN type, having its emitter coupled, preferably connected, to the source of low reference potential GND, and having its base coupled, preferably connected, to the collector of bipolar transistor TB2 and to the base of bipolar transistor TB1; an insulated gate field-effect transistor TM1, also referred to as a MOS transistor, for example, with a P channel, having its source coupled, preferably connected, to a source of power supply voltage Vcc, having its drain coupled, preferably connected, to the collector of bipolar transistor TB1, and having its gate coupled, preferably connected, to the drain; and a MOS transistor TM2, for example, with a P channel, having its source coupled, preferably connected, to the source of power supply voltage Vcc, having its drain coupled, preferably connected, to the collector of bipolar transistor TB2, and having its gate coupled to the gate of MOS transistor TM1. The voltage pbias refers to the voltage at the gate of MOS transistor TM2.

Reference voltage circuit 20 further comprises a circuit for starting the PTAT circuit 30, which is not shown in FIG. 2.

The first amplification stage 40 comprises: a bipolar transistor TB3, for example of NPN type, having its emitter coupled, preferably connected, to a terminal of a resistor R3, the other terminal of resistor R3 being coupled, preferably connected, to the source of low reference potential GND; a bipolar transistor TB4, for example, of NPN type, having its base coupled, preferably connected, to the base of bipolar transistor TB3; a MOS transistor TM3, for example with a P channel, having its source coupled, preferably connected, to the source of power supply voltage Vcc, having its drain coupled, preferably connected, to the collector C_TB3 of bipolar transistor TB3, and having its gate coupled, preferably connected, to the gate of MOS transistor TM2; a MOS transistor TM4, for example, with a P channel, having its source coupled, preferably connected, to the source of power supply voltage Vcc, having its drain coupled, preferably connected, to the collector C_TB4 of bipolar transistor TB4, and having its gate coupled, preferably connected, to the gate of MOS transistor TM2; a MOS transistor TM5, for example, with a P channel, having its source coupled, preferably connected, to the source of power supply voltage Vcc, and having its gate coupled, preferably connected, to the gate of MOS transistor TM2; a MOS transistor TM6, for example, with a P channel, having its source coupled, preferably connected, to the drain of transistor TM5, having its gate coupled, preferably connected, to the collector C_TB3 of bipolar transistor TB3, and having its drain coupled, preferably connected, to the source of low reference potential GND; and a MOS transistor TM7, for example with a P channel, having its source coupled, preferably connected, to the drain of MOS transistor TM5, having its gate coupled, preferably connected, to the base of bipolar transistor TB4, and having its drain coupled, preferably connected, to the base of bipolar transistor TB4.

The second amplification stage 50 comprises: a MOS transistor TM8, for example, with a P channel, having its source coupled, preferably connected, to the source of power supply voltage Vcc, and having its gate coupled, preferably connected, to the gate of transistor TM2; a MOS transistor TM9, for example with an N channel, having its source coupled, preferably connected, to the source of low reference potential GND, having its drain coupled, preferably connected, to the drain of MOS transistor TM8, and having its gate coupled, preferably connected, to the collector C_TB4 of transistor TB4; a bipolar transistor TB5, for example of NPN type, having its base coupled, preferably connected, to the drain of MOS transistor TM9; a MOS transistor TM10, for example with an N channel, having its drain coupled, preferably connected, to the source of power supply voltage Vcc, having its source coupled, preferably connected, to the collector of bipolar transistor TB5, and having its gate receiving a voltage ncasc; and a resistor R4 having a terminal coupled, preferably connected, to the emitter of bipolar transistor TB5, and having its other terminal coupled, preferably connected, to the emitter of transistor TB4, a resistor R5 having a terminal coupled, preferably connected, to the emitter of bipolar transistor TB4, and having its other terminal coupled, preferably connected, to the source of low reference potential GND, and a resistor R6 having a terminal coupled, preferably connected, to the base of bipolar transistor TB5 and having its other terminal coupled, preferably connected, to the source of low reference potential GND.

In the rest of the disclosure, the voltage Vc_TB3 is referred to as the voltage at the collector C_TB3 of bipolar transistor TB3 and the voltage Vc_TB4 is referred to as the voltage at the collector C_TB4 of bipolar transistor TB4. The reference voltage Vbg delivered by circuit 20 corresponds to the voltage across resistor R6. As a variant, it is possible for MOS transistor TM10, which enables to avoid for the voltage at the collector of bipolar transistor TB5 to rise too high, not to be present, the collector of bipolar transistor TB5 then being connectable to the source of power supply voltage Vcc.

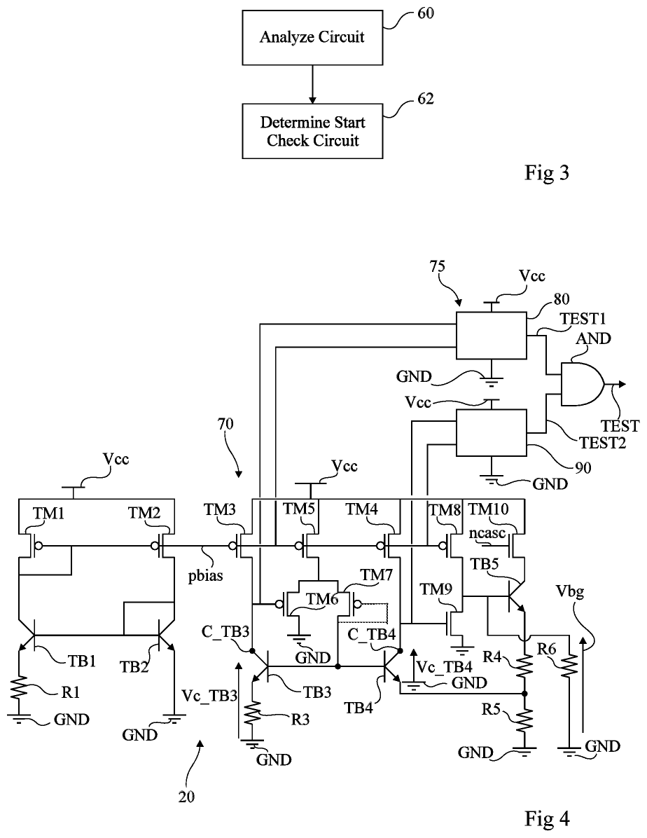

FIG. 3 is a block diagram of an embodiment of a method of design of a start check circuit for a reference voltage circuit.

According to an embodiment, the method comprises a step 60 of analysis of the reference voltage circuit and a step of determination 62 of a start check circuit adapted to the reference voltage circuit.

At step 60, an analysis of the reference voltage circuit is performed to determine the most critical stacks of MOS and/or bipolar transistors of the reference voltage circuit at the starting of the reference voltage circuit. A stack of transistors comprises at least two transistors having their current conduction paths (for example, source-drain paths for MOS transistors) in series between the source of power supply voltage Vcc and the source of low reference potential GND. A critical stack is a stack of transistors of the reference voltage circuit comprising at least two transistors in series between the source of power supply voltage Vcc and the source of low reference potential GND and for which the voltage at an intermediate node of the stack has the highest probability of not reaching a target value if power supply voltage Vcc is not sufficiently high.

According to an embodiment, the critical stack corresponds to a follower assembly. According to another embodiment, the critical stack corresponds to a branch containing the transistor of a differential pair.

For the reference voltage circuit 20 shown in FIG. 2, a first critical stack corresponds to the stack formed by MOS transistors TM5 and TM6, which forms a follower assembly. A second critical stack corresponds to the stack formed by MOS transistors TM8 and TM9, which forms an amplifier assembly.

At step 62, a start check circuit is determined for the reference voltage circuit. The start check circuit comprises an elementary test circuit for each critical stack determined at step 60. Each elementary test circuit receives as an input the voltages received by the tested critical stack and outputs a binary signal in a first logic state, for example, logic state “1”, when the voltage at the intermediate node of the tested critical stack is sufficiently high and at a second logic state, for example, logic state “0”, when the voltage at the intermediate node of the tested critical stack is not sufficiently high. According to the structure of the reference voltage circuit, the start check circuit may comprise a single elementary test circuit, two elementary test circuits, or more than two elementary test circuits. Preferable, the start check circuit comprises at least two elementary test circuits.

According to an embodiment, each elementary test circuit is a copy of at least the tested stack of transistors (MOS or bipolar). The transistors of the duplicated stack of the elementary test circuit receive the same signals as the transistors of the tested stack of the reference voltage circuit. There may further be provided in series with the transistors of the duplicated stack of the elementary test circuit an additional electronic component or additional electronic components, for example, a resistor, a diode, a diode-assembled MOS transistor, etc. The additional electronic component or the additional electronic components are preferably located between the source of low reference potential GND and the duplicated stack and/or between the source of power supply voltage Vcc and the duplicated stack to adjust the voltages between the power terminals of the transistors of the duplicated stack.

According to an embodiment, in the case where the tested critical stack comprises two MOS transistors of opposite type, for example, a P-channel MOS transistor and an N-channel MOS transistor, the elementary test circuit also comprises a stack of a P-channel MOS transistor and of an N-channel MOS transistor and the elementary test signal corresponds to the voltage at the intermediate node between the P-channel MOS transistor and the N-channel MOS transistor. According to an embodiment, in the case where the tested critical stack comprises two MOS transistors of the same type, for example, two P-channel MOS transistors or two N-channel MOS transistors, the elementary test circuit also comprises a first stack of two MOS transistors of this type and further comprises a second stack of a P-channel MOS transistor and of an N-channel MOS transistor. The gate of one of the P-channel MOS transistor or of the N-channel MOS transistor of the second stack is coupled, preferably connected, to the intermediate node between the two transistors of the same type of the first stack, and the elementary test signal corresponds to the voltage at the intermediate node between the P-channel MOS transistor and the N-channel MOS transistor of the second stack.

FIG. 4 shows an equipped reference voltage circuit 70 comprising the reference voltage circuit 20 shown in FIG. 2 and a start check circuit 75. Start check circuit 75 comprises two elementary test circuits 80 and 90. Each elementary test circuit 80 and 90 is coupled to the source of power supply voltage Vcc and to the source of low reference potential GND. First elementary test circuit 80 receives as an input the voltage Vc_TB3 at the collector C_TB3 of bipolar transistor TB3 and the voltage pbias at the gate of transistor TM2 and delivers an elementary binary test signal TEST1. Second elementary test circuit 90 receives as an input the voltage Vc_TB4 at the collector C_TB4 of bipolar transistor TB4 and the voltage pbias at the gate of transistor TM2 and delivers an elementary binary test signal TEST2. According to an embodiment, test circuit 75 further comprises an AND-type logic gate receiving elementary test signals TEST1 and TEST2 and delivering a binary start check signal TEST. Start check signal TEST is at logic state “1” when the two elementary test signals TEST1 and TEST2 are each at logic state “1”, and is at logic state “0” when at least one of elementary test signals TEST1 and TEST2 is at logic state “0”.

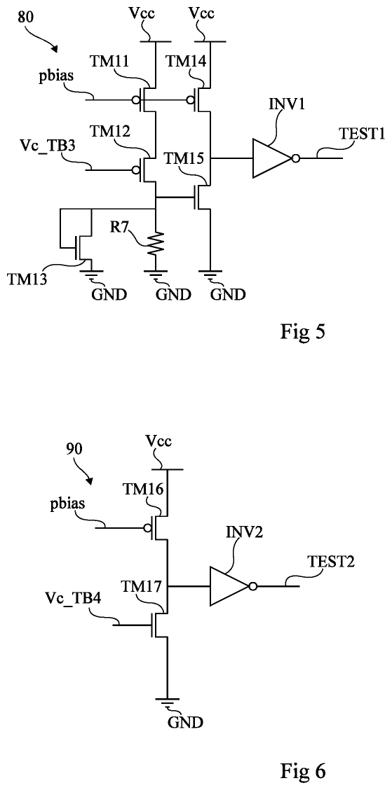

FIG. 5 is an electric diagram of an embodiment of first elementary test circuit 80.

Elementary test circuit 80 comprises: a MOS transistor TM11 (e.g., a replica of transistor TM5), for example, with a P channel, having its source coupled, preferably connected, to the source of power supply voltage Vcc, and having its gate receiving voltage pbias; a MOS transistor TM12 (e.g., a replica of transistor TM6), for example, with a P channel, having its source coupled, preferably connected, to the drain of MOS transistor TM11, and having its gate receiving the voltage Vc_TB3 at the collector of bipolar transistor TB3; a resistor R7 having a terminal coupled, preferably connected, to the drain of MOS transistor TM12, and having its other terminal coupled, preferably connected, to the source of low reference potential GND; a MOS transistor TM13, for example with an N channel, having its source coupled, preferably connected, to the source of low reference potential GND, having its drain coupled, preferably connected, to the drain of MOS transistor TM12, and having its gate coupled, preferably connected, to the drain of MOS transistor TM12; a MOS transistor TM14, for example, with a P channel, having its source coupled, preferably connected, to the source of power supply voltage Vcc, and having its gate receiving voltage pbias; a MOS transistor TM15, for example, with an N channel, having its source coupled, preferably connected, to the source of low reference potential GND, having its drain coupled, preferably connected, to the drain of MOS transistor TM14, and having its gate coupled, preferably connected, to the drain of MOS transistor TM12; and an inverter INV1 having its input coupled, preferably connected, to the drain of transistor TM15.

The signal delivered by inverter INV1 corresponds to the first elementary test signal TEST1.

FIG. 6 is an electric diagram of an embodiment of the second elementary test circuit 90.

Elementary test circuit 90 comprises: a MOS transistor TM16 (e.g., a replica of transistor TM8), for example with a P channel, having its source coupled, preferably connected, to the source of power supply voltage Vcc, and having its gate coupled, preferably connected, to the gate of MOS transistor TM2; a MOS transistor TM17 (e.g., a replica of transistor TM9), for example with an N channel, having its source coupled, preferably connected, to the source of low reference potential GND, having its drain coupled, preferably connected, to the drain of transistor TM16, and having its gate receiving the voltage Vc_TB4 of the collector of bipolar transistor TB4; and an inverter INV2 having its input coupled, preferably connected, to the drain of transistor TM17.

The signal delivered by inverter INV2 corresponds to the second elementary test signal TEST2. Start check circuit 75 has a simple structure and comprises a small number of electronic components. The surface area occupied by start check circuit 75 is decreased with respect to the surface area occupied by reference voltage circuit 20 when these circuits are formed in integrated fashion.

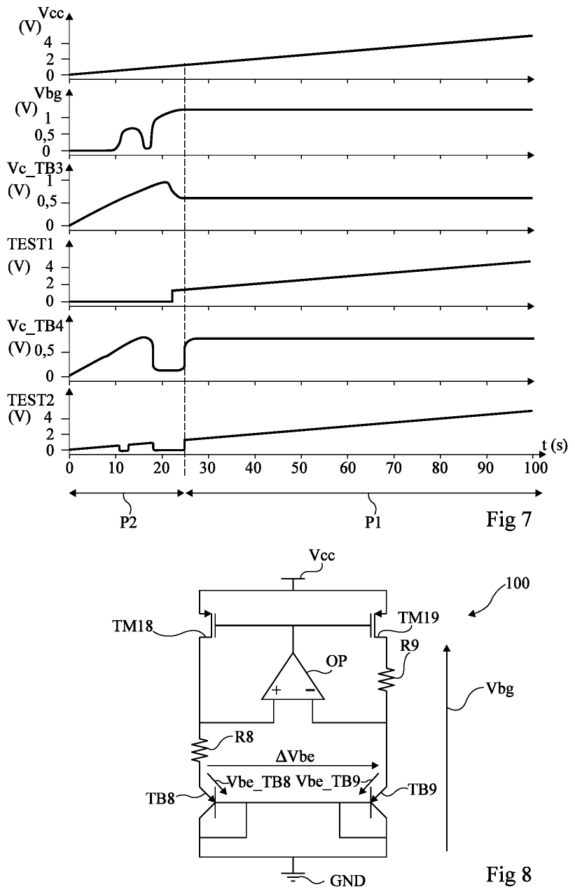

FIG. 7 shows timing diagrams of voltages during the operation of circuit 70 comprising reference voltage circuit 20 equipped with start check circuit 75. In particular, FIG. 7 shows timing diagrams of power supply voltage Vcc, of reference voltage Vbg, of voltage Vc_TB3 at the collector of bipolar transistor TB3, of the first test signal TEST1, of voltage Vc_TB4 at the collector of bipolar transistor TB4, and of the second test signal TEST2.

The variation of voltage Vcc being very slow, the timing diagrams of FIG. 7 are actually representative of a static operation of circuit 75 for different values of power supply voltage Vcc. The first elementary test signal TEST1 is at logic state “1” when it is substantially equal to power supply voltage Vcc and is at logic state “0” when it is substantially equal to 0 V. The second elementary test signal TEST2 is at logic state “1” when it is substantially equal to power supply voltage Vcc and is at logic state “0” when it is substantially equal to 0 V.

In normal operation, the reference voltage Vgb delivered by reference voltage circuit 20 is equal to the desired value, which is in the present equal to 1.2 V. In range P1, that is, for a power supply voltage Vcc greater than approximately 1.4 V, voltage Vbg has the desired value. In range P1, the first elementary test signal TEST1 is at logic state “1” and the second elementary test signal TEST2 is at logic state “1”. In range P2, that is, for a power supply voltage Vcc smaller 1.4 V, voltage Vbg is smaller than the desired value. In range P2, at least one of the first test signal TEST1 and of the second test signal TEST2 is at logic state “0”. It should in particular be noted that, in range P2, the first elementary test signal TEST1 is at logic state “0” when power supply voltage Vcc is smaller than approximately 1 V and is at logic state “1” when power supply voltage Vcc is greater than approximately 1 V, and that the second elementary test signal TEST2 is at logic state “0” over two distinct sub-ranges of power supply voltages Vcc, one of which ends at 1.5 V.

FIG. 8 is an electric diagram of another example of a reference voltage circuit 100.

Circuit 100 comprises: a bipolar transistor TB8, for example of PNP type, having its emitter coupled, preferably connected, to a first terminal of a resistor R8, having its collector coupled, preferably connected, to the source of low reference potential GND, and having its base coupled, preferably connected, to the collector; a bipolar transistor TB9, for example of PNP type, having its emitter coupled, preferably connected, to a first terminal of a resistor R9, having its collector coupled, preferably connected, to the source of low reference potential GND, and having its base coupled, preferably connected, to the collector and to the base of bipolar transistor TB8; a MOS transistor TM18, for example, with a P channel, having its source coupled, preferably connected, to the source of power supply voltage Vcc, and having its drain coupled, preferably connected, to a second terminal of resistor R8; a MOS transistor TM19, for example, with a P channel, having its source coupled, preferably connected, to the source of power supply voltage Vcc, and having its drain coupled, preferably connected, to a second terminal of resistor R9, and having its gate connected to the gate of MOS transistor TM18; and an operational amplifier OP having its non-inverting input (+) coupled, preferably connected, to the second terminal of resistor R8, having its inverting input (−) coupled, preferably connected, to the first terminal of resistor R9, and having its output coupled, preferably connected, to the gates of MOS transistors TM18 and TM19.

Reference voltage circuit 100 delivers reference voltage Vbg to the second terminal of resistor R9. The operating principle of reference voltage circuit 100 is the following: the voltage across resistor R9 increases with temperature while the collector-emitter voltage of bipolar transistor TB9 decreases with temperature, whereby reference voltage Vbg remains constant with temperature by appropriately selecting resistances R8 and R9. In more detailed fashion, bipolar transistor TB8 has an amplification factor greater than 1 with respect to bipolar transistor TB9, whereby the base-emitter voltage Vbe_TB8 of bipolar transistor TB8 is lower than the base-emitter voltage Vbe_TB9 of bipolar transistor TB9. The difference AVbe between voltages Vbe_TB8 and Vbe_TB9 is proportional to the absolute temperature. Operational amplifier OP imposes for the voltages at its inverting and non-inverting inputs to be equal, so that the current flowing through resistor R8 is equal to ΔVbe/R8. The current mirror formed by MOS transistors TM18 and TM19 imposes for the current flowing through resistor R9 to also be equal to ΔVbe/R8. Voltage Vbg is then equal to the sum of the voltage across resistor R9, equal to R9*ΔVbe/R8, and of the base-emitter voltage of bipolar transistor TB9. Many variants of the circuit of FIG. 8 are possible.

The implementation of the design method previously described in relation with FIG. 3 for the reference voltage circuit 100 of FIG. 8 results in determining that at least one critical stack forms part of the operational amplifier.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. An electronic circuit, comprising:
a reference voltage circuit; and
a circuit configured to check starting operation of the reference voltage circuit;
wherein the reference voltage circuit comprises:
at least one first stack of a first transistor and a second transistor, wherein the first transistor comprises a first control terminal configured to receive a first control signal, and wherein the second transistor comprises a second control terminal configured to receive a second control signal;
wherein the circuit configured to check starting operation comprises:
at least one first elementary test circuit including a second stack of a third transistor and a fourth transistor configured to deliver a first binary signal, wherein the third transistor is of a same type as the first transistor and comprises a third control terminal configured to receive the first control signal, and wherein the fourth transistor is of a same type as the second transistor and comprises a fourth control terminal configured to receive the second control signal.

2. The electronic circuit according to claim 1, wherein the reference voltage circuit is configured to be connected to a source of a power supply voltage and to a source of a reference potential, wherein the first transistor and the second transistor are series-coupled between the source of the power supply voltage and the source of the reference potential, and wherein the third transistor and the fourth transistor are series-coupled between the source of the power supply voltage and the source of the reference potential.

3. The electronic circuit according to claim 1, wherein the first, second, third, and fourth transistors are MOS transistors.

4. The electronic circuit according to claim 1, wherein the first transistor is of a same type as the second transistor, wherein the first elementary test circuit further comprises a fifth transistor in series with a sixth transistor, wherein the fifth transistor comprises a fifth control terminal configured to receive the first control signal, wherein the sixth transistor comprises a sixth control terminal configured to receive a signal at an intermediate node of the second stack, and wherein the first binary signal corresponds to a voltage at the junction node between the fifth transistor and the sixth transistor.

5. The electronic circuit according to claim 1:
wherein the reference voltage circuit further comprises at least one third stack of a seventh transistor and an eighth transistor, wherein the seventh transistor comprises a seventh control terminal configured to receive a third control signal, and wherein the eighth transistor comprises an eighth control terminal configured to receive a fourth control signal; and
wherein the start check circuit further comprises at least one second elementary test circuit comprising a fourth stack of a ninth transistor and a tenth transistor configured to deliver a second binary signal, wherein the ninth transistor is of a same type as the seventh transistor and comprises a ninth control terminal configured to receive the third control signal, and wherein the tenth transistor is of a same type as the eighth transistor and comprises a tenth control terminal configured to receive the fourth control signal.

6. The electronic circuit according to claim 5, wherein the third control signal is identical to the first control signal.

7. The electronic circuit according to claim 5, wherein the reference voltage circuit is configured to be connected to a source of a power supply voltage and to a source of a reference potential, wherein the first transistor and the second transistor are series-coupled between the source of the power supply voltage and the source of the reference potential, and wherein the third transistor and the fourth transistor are series-coupled between the source of the power supply voltage and the source of the reference potential.

8. The electronic circuit according to claim 7, wherein the seventh transistor and the eighth transistor are series-coupled between the source of the power supply voltage and the source of the reference potential, and wherein the ninth transistor and the tenth transistor are series-coupled between the source of the power supply voltage and source of the reference potential.

9. The electronic circuit according to claim 5, wherein the seventh transistor and the eighth transistor are of different types, and wherein the second binary signal corresponds to the voltage at a junction node between the ninth transistor and the tenth transistor.

10. The electronic circuit according to claim 5, wherein the seventh, eighth, ninth, and tenth transistors are MOS transistors.

11. The electronic circuit according to claim 5, further comprising:
a proportional to absolute temperature (PTAT) circuit;
a first amplification stage; and
a second amplification stage;
wherein the first amplification stage comprises an eleventh transistor and a twelfth transistor; and
wherein the second control signal is a voltage at a power terminal of the eleventh transistor, and the fourth control signal is a voltage at a power terminal of the twelfth transistor.

12. A method of designing an electronic circuit which includes a reference voltage circuit and a circuit for checking starting operation of the reference voltage circuit, the method comprising:
identifying, in the reference voltage circuit, at least one first stack of a first transistor and of a second transistor, wherein the first transistor comprises a first control terminal configured to receive a first control signal, and the second transistor comprises a second control terminal configured to receive a second control signal; and
including, in the start check circuit, at least one first elementary test circuit comprising a second stack of a third transistor and a fourth transistor configured to deliver a first binary signal, wherein the third transistor is of a same type as the first transistor and comprises a third control terminal configured to receive the first control signal, and wherein the fourth transistor is of a same type as the second transistor and comprises a fourth control terminal configured to receive the second control signal.

13. An electronic circuit, comprising:
a reference voltage circuit including a first stack of transistors; and
a circuit configured to check starting operation of the reference voltage circuit;
wherein the circuit configured to check starting operation comprises a second stack of transistors;
wherein the second stack of transistors is a replica of the first stack of transistors;
wherein one or more signals input to the first stack of transistors are also input to the second stack of transistors; and
wherein an output of the second stack of transistors provides a first test signal.

14. The electronic circuit of claim 13:
wherein the reference voltage circuit further includes a third stack of transistors;
wherein the circuit configured to check starting operation further comprises a fourth stack of transistors;
wherein the fourth stack of transistors is a replica of the third stack of transistors;
wherein one or more signals input to the third stack of transistors are also input to the fourth stack of transistors; and
wherein an output of the fourth stack of transistors provides a second test signal.

15. The electronic circuit of claim 14, further comprising a logic circuit configured to logically combine the first and second test signals to generate a test output signal indicative of proper starting operation of the reference voltage circuit.

16. The electronic circuit of claim 13, wherein the reference voltage circuit is configured to be connected to a source of a power supply voltage and to a source of a reference potential, wherein the first stack of transistors are coupled between the source of the power supply voltage and the source of the reference potential, and wherein the second stack of transistors are coupled between the source of the power supply voltage and the source of the reference potential.
